(19) United States
(12) Patent Application Publication
(10) Pub. No.: US 2010/0289087 A1
(43) Pub. Date: Nov. 18, 2010

(54) SEMICONDUCTOR DEVICE AND METHOD OF MANUFACTURING A SEMICONDUCTOR DEVICE

(75) Inventor: Jun Hasegawa, Tokyo (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/779,393

(22) Filed: May 13, 2010

(30) Foreign Application Priority Data
May 18, 2009 (JP) 2009-119696

(51) Int. Cl. H01L 27/06; H01L 21/8234; H01L 21/02

(52) U.S. Cl. 257/380; 438/238; 257/E27.016; 257/E21.616; 257/E21.004

(57) ABSTRACT

A semiconductor substrate with an active element formed in the semiconductor substrate, an element isolating insulating film formed around the active element and semiconductor substrate, a polysilicon resistance element formed over the element isolating insulating film with terminal areas and a resistance portion formed between the terminal areas, the polysilicon resistance element having plural reticulations which have the same shapes and the same size.

### CROSS REFERENCE TO RELATED APPLICATIONS

This application is based upon and claims the benefit of priority from the prior Japanese Application No. 2009-119696, filed May 18, 2009, the entire contents of which are incorporated herein by reference.

### TECHNICAL FIELD

This disclosure relates to a semiconductor device which has a polysilicon resistance element, and a method of manufacturing the semiconductor device.

### BACKGROUND

A polysilicon resistance element is generically used in a semiconductor device, such as an analog LSI (Large-Scale Integration). A semiconductor device, which has a polysilicon resistance element on an insulating film covering a semiconductor substrate, is disclosed in US Patent Application Publication No. 2005/0082639 A1.

Some manufacturing errors are observed in the manufacturing process of a polysilicon resistance element. For example, if a designed width of a polysilicon resistance element is “W” and a designed length of a polysilicon resistance element is “L”, a manufacturing error in the width direction “ΔW′ and a manufacturing error in the length direction “ΔL” may be observed. In situations where manufacturing errors occur, a designed resistance value “Ω” of a polysilicon resistance element is different from an actual resistance value, because of the manufacturing error of resistance “ΔΩ”. An effect, which ΔL makes to ΔΩ, is able to ignore, because a length of a polysilicon resistance element is long enough. ΔΩ reduces the accuracy of a circuit of semiconductor device, such as an analog LSI.

A polysilicon resistance element is thickly formed into planar rectangle shape. For this reason, ΔΩ is predisposed to the effect of ΔW and ΔΩ becomes bigger.

Therefore, it is very difficult to accurately manufacture a polysilicon resistance element, which has a designed resistance value Ω, without a manufacturing error of resistance ΔΩ.

### SUMMARY

An advantageous aspect of the devices and methods described herein is to provide a semiconductor device with a polysilicon resistance element which has an approximate designed resistance value, and a method of the manufacturing the semiconductor device.

In order to achieve the above-described advantage, a first aspect of the invention involves a semiconductor substrate; an active element formed in the semiconductor substrate; an element isolating insulating film formed around the active element and in the semiconductor substrate; a polysilicon resistance element, formed over the element isolating insulating film, comprising terminal areas and a resistance portion formed between the terminal areas; wherein the polysilicon resistance element has plural reticulations which have the same shapes and the same size.

### BRIEF DESCRIPTION OF THE DRAWINGS

FIG. 1 is a cross-sectional view of a semiconductor device of a first embodiment;

FIG. 2 is a A1-A2 plain view of a polysilicon resistance element;

FIG. 3 is a B1-B2 cross-sectional view of a polysilicon resistance element;

FIG. 4 is a cross-sectional view of the semiconductor device manufactured according to the first embodiment of a method in accordance with the invention;

FIG. 5 is a cross-sectional view of the semiconductor device manufactured according to the first embodiment of a method in accordance with the invention;

FIG. 6 is a cross-sectional view of the semiconductor device manufactured according to the first embodiment of a method in accordance with the invention;

FIG. 7 is a cross-sectional view of the semiconductor device manufactured according to the first embodiment of a method in accordance with the invention;

FIG. 8 is a plain view of a polysilicon resistance element of the another version of the first embodiment;

FIG. 9 is a plain view of a polysilicon resistance element of the another version of the first embodiment;

FIG. 10 is a plain view of a polysilicon resistance element of the second embodiment;

FIG. 11 is a plain view of a polysilicon resistance element of another version of the second embodiment;

FIG. 12 is a plain view of a polysilicon resistance element of the third embodiment;

FIG. 13 is a plain view of a polysilicon resistance element of another version of the third embodiment; and

FIG. 14 is a plain view of a polysilicon resistance element of another version of the invention.

### DETAILED DESCRIPTION

Embodiments of the devices and methods described herein will be explained in reference to the drawings as follows.

### First Embodiment

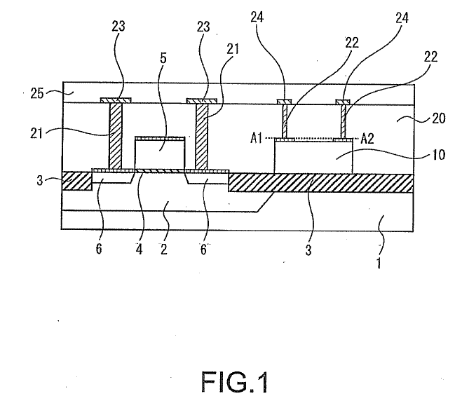

FIG. 1 is a cross-sectional view of a semiconductor device of a first embodiment.

The semiconductor device of the first embodiment has a silicon substrate 1 as a semiconductor substrate, a well 2, an element isolating insulating film 3, a gate insulating film 4, a gate electrode 5, a diffused layer 6 as a source and drain region, a polysilicon resistance element 10, a first interlayer dielectric film 20, contact electrodes 21 and 22, a wiring for a source/drain region 23, a wiring for a resistive element 24, and a second interlayer dielectric film 25.

A MOS (Metal-Oxide-Semiconductor) transistor Tr, an active element, comprises the well 2, the gate insulating film 4, the gate electrode 5, the diffused layer 6, the contact electrode 21, and the wiring for a source/drain region 23. A resistive element RE comprises the polysilicon resistance element 10, the contact electrode 22, and the wiring for a resistive element 24.

The contact electrode 21 of the transistor Tr electrically connects the wiring for a source/drain region 23 with the gate electrode 5. The contact electrode, 22 of the resistive element RE electrically connects the wiring for a resistive element 24 with the polysilicon resistance element 10.

The MOS transistor Tr is formed above a principle surface of the silicon substrate 1 surrounded by the element isolating insulating film 3, that is above the well 2. The gate electrode 5 of the MOS transistor Tr is formed above the well 2 through the gate insulating film 4, and the diffused layer 6 is formed in the well 2.

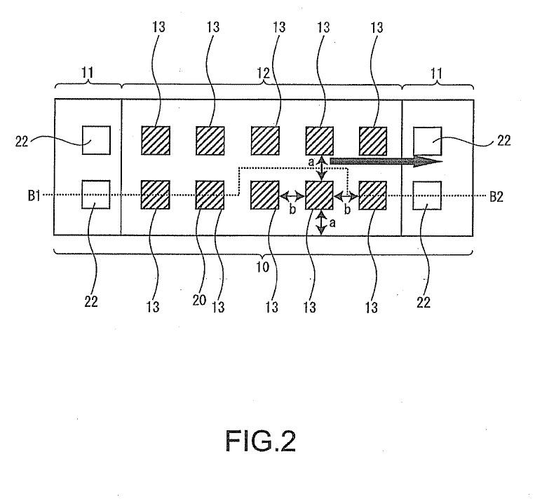

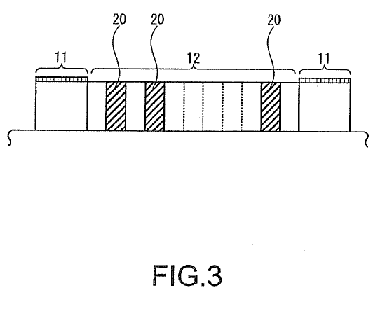

FIG. 2 is an A1-A2 of FIG. 1 plain view of a polysilicon resistance element, and FIG. 3, is a B1-B2 of FIG. 2 cross-sectional view of a polysilicon resistance element.

The polysilicon resistance element 10 is formed above the element isolating insulating film 3. The polysilicon resistance element 10 is a polysilicon film shaped a planar rectangle, and comprises terminal areas 11 formed at both ends of the polysilicon film, and a resistance portion 12, which is a portion of the polysilicon film, formed between the terminal areas 11. The resistance portion 12 is linearly formed, and also formed of a net-like structure having plural reticulations 13. The plural reticulations 13 are formed M rows×N rows, for example 2 rows×5 rows. In other words, for this embodiment, a polysilicon resistance element thickly formed, whose width is W and length is L, is divided into M for width direction and N for length direction.

Each of the plural reticulations 13 is formed same size regular tetragon, and each of grating spaces of the plural reticulations 13 is same space. In other words, the grating spaces “a” of the width W direction and the grating spaces “b” of the length L direction is formed same size. The first interlayer dielectric film 20 is also formed in the plural reticulations 13.

For the first embodiment, the terminal areas 11 comprise a polysilicon film and metal silicide film. The terminal areas 11 can be also formed by adding conductive impurities in high concentration. At the polysilicon resistance element 10, a current flows in a direction shown by the arrowed line (to the right in FIG. 2), when a voltage is applied to between the terminal areas.

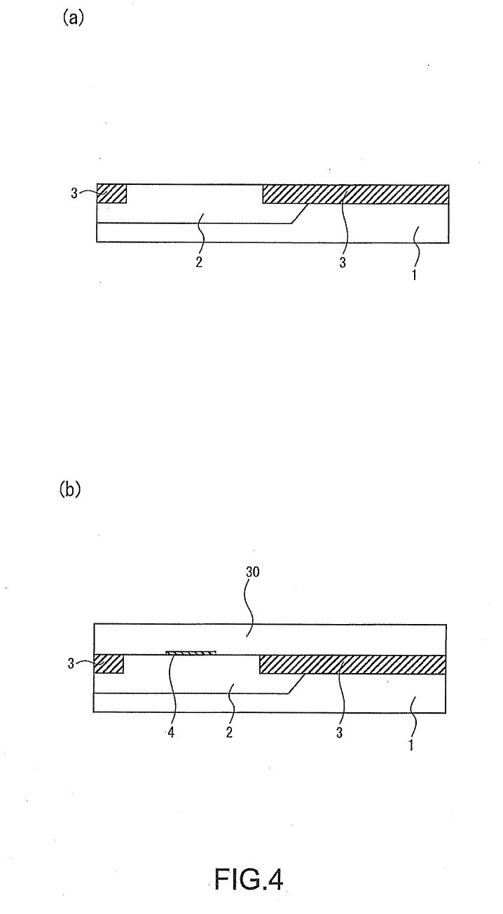

FIG. 4 to FIG. 7 are cross-sectional views of the semiconductor device manufactured according to the first embodiment of a method in accordance with the invention.

As shown by FIG. 4(a), the well 2 is formed in the silicon substrate 1 as a semiconductor substrate, and the element isolating insulating film 3 is formed in or around an area of the well 2, where an element will be formed in subsequent processing. As shown by FIG. 4(b), an oxide film as the gate insulating film 4 is formed on the principal surface of the silicon substrate 1, and a polysilicon film 30, which will subsequently form the gate electrode 5 and the polysilicon resistance element 10, is formed on the principal surface of the silicon substrate 1 and the gate insulating film 4.

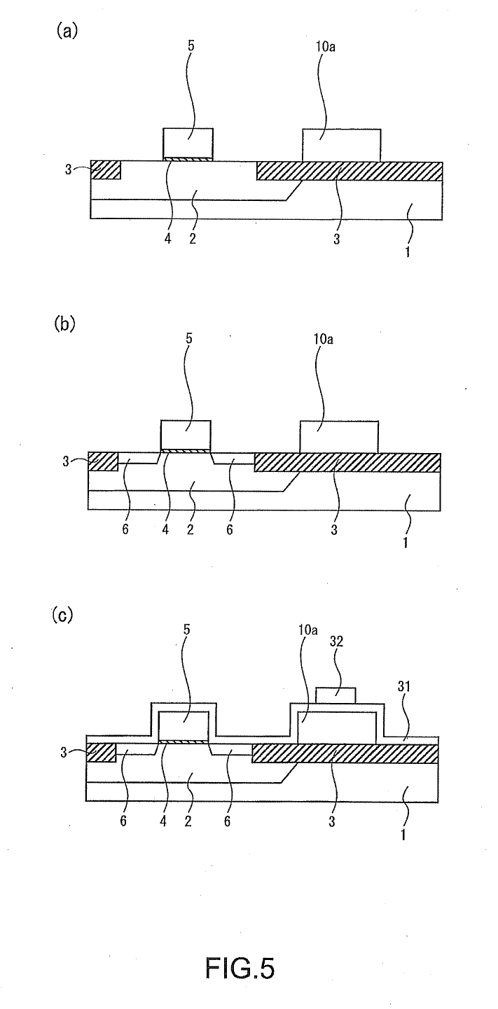

As shown by FIG. 5(a), a resist pattern (not shown in the figure) for forming the gate electrode 5 and the polysilicon resistance element 10 is formed by lithography. The gate electrode 5 and a polysilicon film 10a which will subsequently form the polysilicon resistance element 10 are formed by etching using the resist pattern for a mask. The polysilicon film 10a is formed of a net-like structure having plural reticulations 13 (not shown in the figure), which are formed M rows×N rows, for example 2 rows×5 rows. Each of the plural reticulations 13 is formed of a regular tetragon each having the same size (or substantially the same size), and each of the grating spaces of the plural reticulations 13 has the same pitch. In other words, the grating spaces of the width W direction and the grating spaces of the length L direction are formed of the same size, as shown by FIG. 2 and FIG. 3.

After removing the resist pattern, as shown by FIG. 5(b), an impurity, having an opposite conductivity type from a conductivity type of the well 2, is injected in the well 2 by using the gate electrode 5 as a mask. And the diffused layer 6 is formed on both sides of the gate electrode 5 by an annealing treatment of the injected impurity. At the same time, an impurity can be injected to determine the resistance value of the polysilicon resistance element 10.

As shown by FIG. 5(c), an oxide film 31 is formed on the principal surface of the silicon substrate 1, the gate electrode 5 and the polysilicon film 10a, to prevent undesired silicide formation. A resist pattern 32 is formed on the area, under where the resistance portion 12 will be subsequently formed, of the oxide film 31.

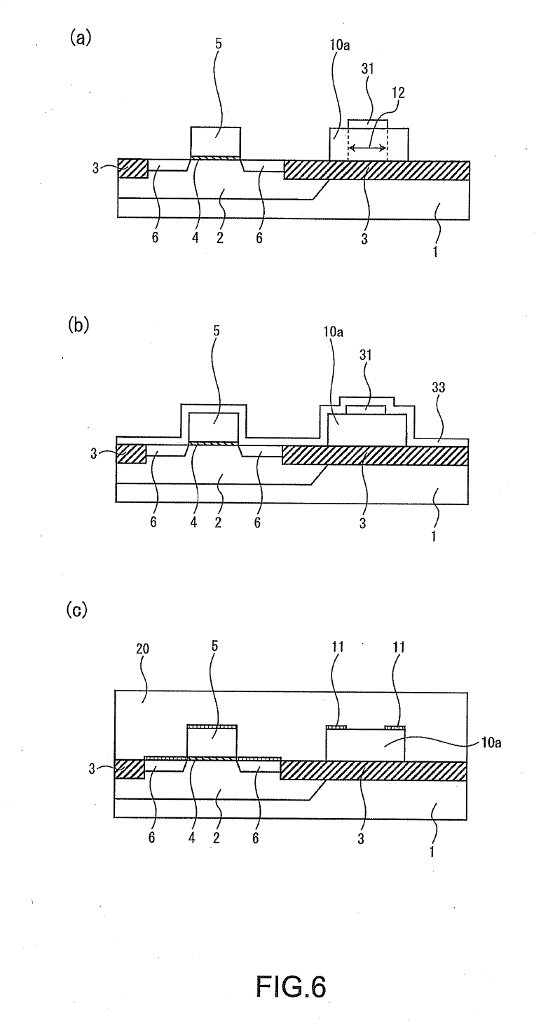

As shown by FIG. 6(a), by using the resist pattern 32 (not shown in the figure) and an etching, the oxide film 31 is removed except the area under which the resistance portion 12 will be formed.

As shown by FIG. 6(b), a metal layer 33, for example Ti, Co, or alloys thereof, is formed on the principal surface of the silicon substrate 1, the gate electrode 5, the polysilicon film 10a and the oxide film 31. By a heat treatment, the both side of the polysilicon film 10a and a polysilicon film of the gate electrode 5 react with the metal layer 33, and form a silicide. Then, because a sidewall (not shown in the figure) is formed on each side of the polysilicon film 10a, the terminal areas 11, that are made of a metal layer, are formed on only the upper side of the both ends of the polysilicon resistance element 10. Equally, because a sidewall (not shown in the figure) is formed on each side of the gate electrode 5, a silicide metal layer is only formed on the upper surface of the gate electrode 5. A silicide metal layer is also formed on the diffused layer 6. Then the metal layer 33 and the oxide film 31 are removed except for the terminal areas 11.

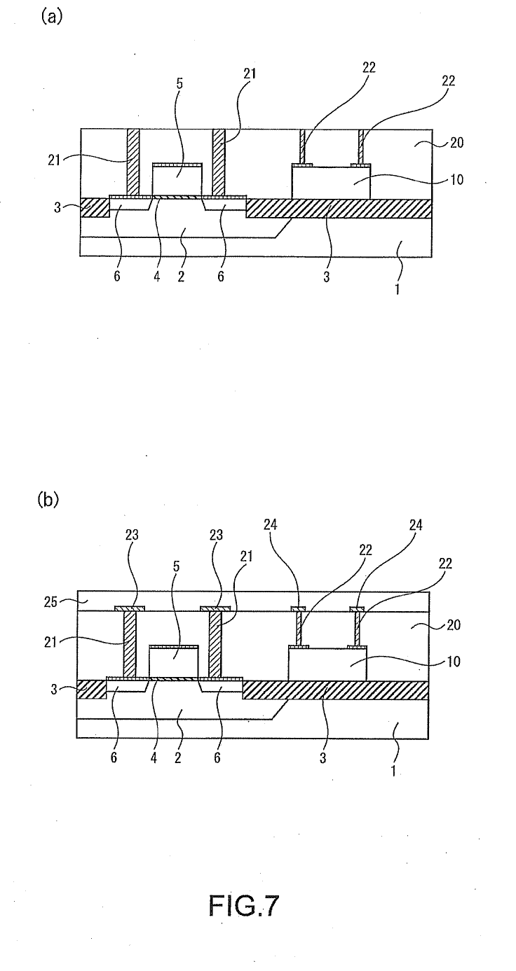

As shown by FIG. 6(c), the first interlayer dielectric film 20 is formed on or over the silicon substrate 1, the gate electrode 5 and the polysilicon resistance element 10. After forming the first interlayer dielectric film 20, as shown by FIG. 7(a), a resist pattern (not shown in the figure) is formed by lithography to form the contact electrodes 21 and 22. And contact holes, each connecting the diffused layer 6 with the terminal areas 11 of the polysilicon resistance element 10, are formed in the first interlayer dielectric film 20 by using the resist pattern for a mask. The contact electrodes 21 and 22 are formed by implanting an electrical conductor, for example but not limited to tungsten, into the contact holes.

As shown by FIG. 7(b), the wirings for a source/drain region 23 are formed on the contact electrodes 21 and the wirings for a resistive element 24 are formed on the contact electrodes 22. The second interlayer dielectric film 25 is formed on the wirings for a source/drain region 23, the wirings for a resistive element 24 and the first interlayer dielectric film 20.

The embodiment noted above has the following effect.

The resistance portion 12 of the polysilicon resistance element 10 of the embodiment is formed of a net-like structure having plural reticulations 13. The plural reticulations 13 are formed of M rows×N rows. Because the resistance portion 12 is divided into M parts in the width direction, ΔW statistically becomes 1/√M×ΔW compared to a polysilicon resistance element which is thickly formed into planar rectangle shape.

For that reason, a manufacturing error of resistance ΔΩ caused by a manufacturing error of width direction ΔW is decreased compared to the existing polysilicon resistance element. We can easily manufacture the polysilicon resistance element which has a resistance value which is approximate a designed value.

### (Another Version #1 of the First Embodiment)

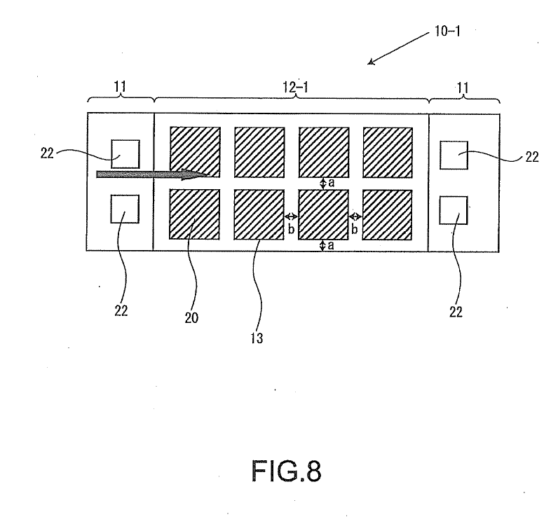

FIG. 8 is a plain view of a polysilicon resistance element of another version of the first embodiment.

As shown by FIG. 8, the sizes of all of the plural reticulations 13 can be equally increased and decreased, as desired. At the polysilicon resistance element 10-1, the grating spaces “a” of the width W direction and the grating spaces “b” of the length L direction are equally decreased.

Therefore the resistance value Ω can be changed without increasing or decreasing the size of the polysilicon resistance element. In this version of the first embodiment, the resistance value Ω is increased compared with the first embodiment.

Yet another version #1 of the first embodiment can also get the same benefit of the first embodiment.

### (Yet Another Version #2 of the First Embodiment)

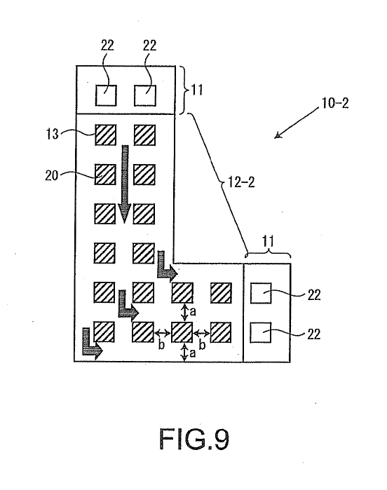

FIG. 9 is a plain view of a polysilicon resistance element of the yet another version of the first embodiment.

As shown by FIG. 9, the polysilicon resistance element 10 can be formed in a nonlinearity shape. A polysilicon resistance element 10-2 is formed as L-shaped structure. The terminal areas 11 are formed at both ends of the polysilicon film, and plural reticulations 13 are formed at the resistance portion 12-2 formed between the terminal areas 11.

Another version #2 of the first embodiment can also get the same benefit of the first embodiment.

### Second Embodiment

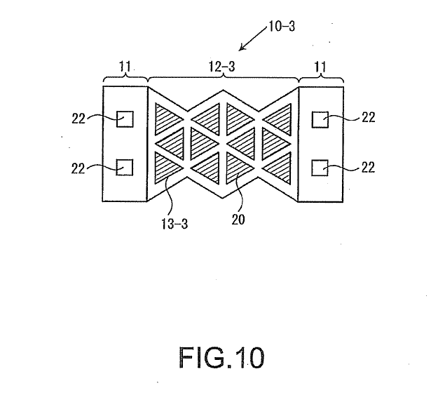

FIG. 10 is a plain view of a polysilicon resistance element of the second embodiment. In the second embodiment, all structures except the polysilicon resistance element have the same structure as the structure of the first embodiment. Therefore an explanation of all structures except the polysilicon resistance element is skipped for brevity.

As shown by FIG. 10, at the polysilicon resistance element 10-3, a resistance portion 12-3 is linearly formed, and also formed of a net-like structure having plural reticulations 13-3. The plural reticulations 13-3 are formed M rows×N rows, for example 3 rows×4 rows in matrix state. The plural reticulations 13-3 are also formed having the same size equilateral-triangular shapes.

For this embodiment, a polysilicon resistance element is formed, whose width is W and length is L, is divided into M for width direction and N for length direction.

The second embodiment can also obtain the same benefit of the first embodiment.

### (Another Version of the Second Embodiment)

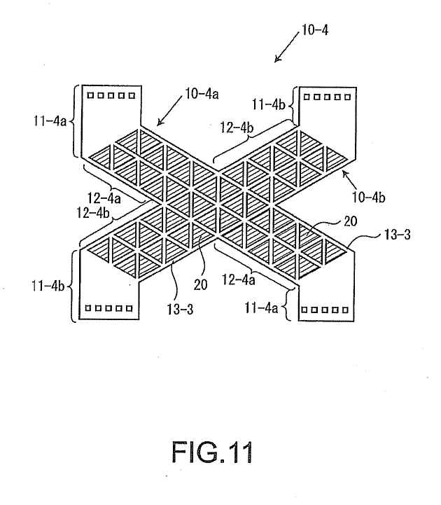

FIG. 11 is a plain view of a polysilicon resistance element of another version of the second embodiment.

As shown by FIG. 11, the polysilicon resistance element 10-4 can be formed having a nonlinearity shape, for example an “X” shape. In other words, the polysilicon resistance element 10-4 comprises the first the polysilicon resistance element 10-4a and the second the polysilicon resistance element 10-4b. The terminal areas 11-4a are formed at both ends of the polysilicon film, and plural reticulations 13-3 are formed at the resistance portion 12-4a formed between the terminal areas 11-4a. And the terminal areas 11-4b are formed at both ends of the polysilicon film, and plural reticulations 13-3 are formed at the resistance portion 12-4b formed between the terminal areas 11-4b.

Another version of the second embodiment can also obtain the same benefit of the first embodiment.

Same as another version #1 of the first embodiment, at this polysilicon resistance element 10-3, 10-4, the grating spaces of the width direction and the grating spaces of the length direction can be increased or decreased, as desired.

### Third Embodiment

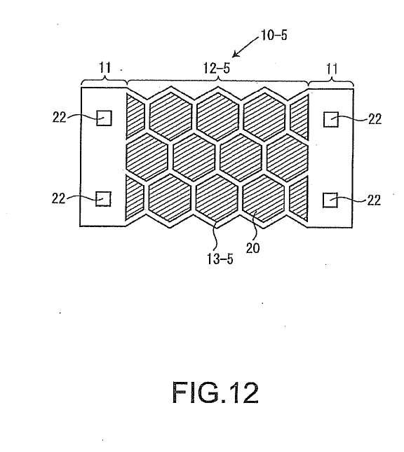

FIG. 12 is a plain view of a polysilicon resistance element of the third embodiment. In the third embodiment, all structures except the polysilicon resistance element are the same as the structures of the first embodiment. Therefore an explanation of all structures except the polysilicon resistance element is skipped for brevity.

As shown by FIG. 12, at the polysilicon resistance element 10-5, a resistance portion 12-5 is linearly formed, and also formed of a net-like structure having plural reticulations 13-5. The plural reticulations 13-5 are formed M rows×N rows, for example 3 rows×5 rows. The plural reticulations 13-5 are also formed having the same size regular hexagon shapes or a honeycomb structure.

For this embodiment, a polysilicon resistance element is formed, whose width is W and length is L, is divided into M for width direction and N for length direction.

The third embodiment can also obtain the same benefit of the first embodiment.

### (Another Version of the Third Embodiment)

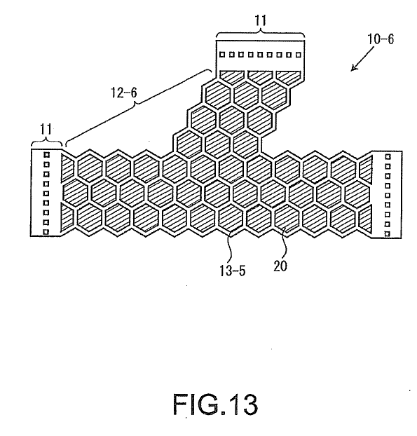

FIG. 13 is a plain view of a polysilicon resistance element of another version of the third embodiment.

As shown by FIG. 13, the polysilicon resistance element 10-6 can be formed having a nonlinearity shape, for example a “y” shape. The terminal areas 11 are formed at all of the three pointy ends of the polysilicon film, and plural reticulations 13-5 are formed at the resistance portion 12-6.

Another version of the third embodiment can also obtain the same benefit of the first embodiment.

Same as another version #1 of the first embodiment, at this polysilicon resistance element 10-5, 10-6, the grating spaces of the width direction and the grating spaces of the length direction can be increased or decreased as desired.

Numerous modifications and variations of the invention are possible in light of the above teachings. It is therefore to be understood that, within the scope of the appended claims, the invention can be practiced in a manner other than as specifically described herein.

The invention can cause secondary effects as mentioned below.

In general, the grains of the polysilicon resistance element grow larger through a heat treatment process, for example the annealing treatment for forming the diffused layers.

The controllable factors for determining the growth rate of the grains include film thickness and width W ratio, as well as the identity of an atmosphere gas for the heat treatment. Therefore, the growth of the grains in the heat treatment depends on the width W of the polysilicon resistance element. For example if the width W is doubled, the growth rate of the grains is also changed compared to the polysilicon resistance element whose width is only W.

A resistivity of the polysilicon resistance element depends on the size of the grains; that is, the width W of the polysilicon resistance element because a current also flows across the grain boundaries.

According to this invention, in case that the width W of the polysilicon resistance element is grown wider, a manufacturing error of resistance ΔΩ caused by the size of grains can be decreased because the polysilicon resistance element has the same size plural reticulations, for example a regular tetragon, and each of the grating spaces of the plural reticulations is same space (constant pitch). Therefore the polysilicon resistance element which has a resistance value which is approximate of a designed value can be easily manufactured.

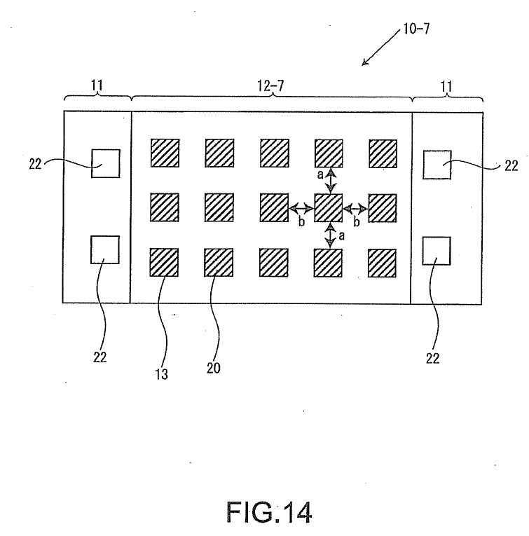

The resistance value can be changed by increasing or decreasing the quantity of the reticulations. As shown by FIG. 14, the polysilicon resistance element 10-7 has more reticulations than the polysilicon resistance element 10 as shown by FIG. 2. In this case, provided that the grating spaces “a” of the width W direction are same at FIG. 2 and FIG. 14, the resistance value of the polysilicon resistance element 10-7 is three fourths of the resistance value of the polysilicon resistance element 10.

As mentioned above, according to this invention, by forming a different number of the reticulations, the polysilicon resistance elements whose the resistance values is different each other can be formed on one chip.

Although the invention is shown and described with respect to certain illustrated aspects, it will be appreciated that equivalent alterations and modifications will occur to others skilled in the art upon the reading and understanding of this specification and the annexed drawings. In particular regard to the various functions performed by the above described components, the terms used to describe such components are intended to correspond, unless otherwise indicated, to any component which performs the specified function of the described component (e.g., that is functionally equivalent), even though not structurally equivalent to the disclosed structure, which performs the function in the herein illustrated exemplary aspects of the invention.

What is claimed is:

1. A semiconductor device comprising:
a semiconductor substrate;
an active element formed in the semiconductor substrate;
an element isolating insulating film formed around the active element and in the semiconductor substrate; and
a polysilicon resistance element, formed over the element isolating insulating film, comprising terminal areas and a resistance portion formed between the terminal areas;
wherein the polysilicon resistance element has plural reticulations which are same shapes and same size.

2. A semiconductor device according to claim 1, wherein a center point of the each plural reticulations is aligned at regular intervals.

3. A semiconductor device according to claim 1, wherein the active element is MOS transistor.

4. A semiconductor device according to claim 1, wherein shapes of the plural reticulations are polygonal shapes which can be arranged in a plane.

5. A semiconductor device according to claim 1, wherein the reticulations have an equilateral triangle shape.

6. A semiconductor device according to claim 1, wherein the reticulations have a regular tetragon shape.

7. A semiconductor device according to claim 1, wherein the reticulations have a regular hexagon shape.

8. A semiconductor device according to claim 1, the resistance portion is formed in a linear fashion.

9. A semiconductor device according to claim 1, the resistance portion is formed in a nonlinear fashion.

10. A method of forming a semiconductor device, comprising:
forming an element isolating insulating film around an active element area and in a semiconductor substrate;
forming a gate insulating film over the semiconductor substrate;
forming a polysilicon film over the semiconductor substrate and the gate insulating film;
forming a polysilicon resistance element, which comprises terminal areas and a resistance portion formed between the terminal areas, over the element isolating insulating film;
forming a gate electrode over the gate insulating film at the active element area;
forming source and drain regions in the active element area by using the gate electrode for a mask;
forming an interlayer dielectric film over the semiconductor substrate, the polysilicon resistance element and the gate electrode; and
forming a contact electrode, which connects both ends of the polysilicon resistance element, in the interlayer dielectric film;
wherein, in forming the polysilicon resistance element, plural reticulations, which have same shapes and same size, are formed at the resistance portion of the polysilicon resistance element.

11. A method of forming a semiconductor device according to claim 10, wherein a center point of the each plural reticulation is aligned at regular intervals.

12. A method of forming a semiconductor device according to claim 10, wherein shapes of the plural reticulations are polygonal shapes which can be arranged in a plane.

13. A method of forming a semiconductor device according to claim 10, wherein the reticulations have an equilateral triangle shape.

14. A method of forming a semiconductor device according to claim 10, wherein the reticulations have a regular tetragon shape.

15. A method of forming a semiconductor device according to claim 10, wherein the reticulations have a regular hexagon shape.

16. A method of forming a semiconductor device according to claim 10, the resistance portion is formed in a linear fashion.

17. A method of forming a semiconductor device according to claim 10, the resistance portion is formed in a nonlinear fashion.
